(19) United States
(12) Patent Application Publication
(10) Pub. No.: US 2019/0304880 A1
(43) Pub. Date: Oct. 3, 2019

(54) SEMICONDUCTOR MODULE

(71) Applicant: FUJITSU COMPONENT LIMITED, Tokyo (JP)

(72) Inventors: Mitsuki Kanda, Tokyo (JP); Takatoshi Yagisawa, Tokyo (JP)

(21) Appl. No.: 16/363,164

(22) Filed: Mar. 25, 2019

(30) Foreign Application Priority Data
Mar. 28, 2018 (JP) 2018-062431

(51) Int. Cl. H01L 23/498; H01L 31/0224; H01L 23/552; G02B 6/42; H05K 1/11

(52) U.S. Cl. CPC H01L 23/4985; H01L 31/0224; H05K 1/118; G02B 6/4201; H01L 23/552

(57) ABSTRACT

A semiconductor module includes a first circuit board, a second circuit board, a first semiconductor device mounted on a first surface of the first circuit board, a second semiconductor device mounted on the second circuit board, and a radio wave absorber disposed between the first circuit board and the second circuit board.

### CROSS-REFERENCE TO RELATED APPLICATION

The present application is based on and claims priority to Japanese Patent Application No. 2018-062431, filed on Mar. 28, 2018, the entire contents of which are incorporated herein by reference.

### BACKGROUND OF THE INVENTION

### 1. Field of the Invention

An aspect of this disclosure relates to a semiconductor module.

### 2. Description of the Related Art

In a large-scale computer system or a supercomputer, multiple processing units are connected to each other by optical interconnection to achieve high-speed processing. The optical interconnection is comprised of an optical module including optical transmitters and light-receiving elements, and optical fibers. In the optical module, to reduce its size, multiple optical transmitters and multiple optical receivers are mounted at high density on a board. The optical module uses an optical signal modulated at high frequency (Japanese Laid-Open Patent Publications No. 2003-134051, No. 2001-127561, and No. 2003-224408.

In a semiconductor module such as an optical module using a high-frequency signal, a semiconductor device for processing the high-frequency signal mounted on a circuit board may be affected by an electromagnetic wave generated by the operation of another semiconductor device mounted on another circuit board of the semiconductor module, and the operation of the semiconductor device for processing the high-frequency signal may become unstable.

For this reason, there is a demand for a semiconductor module where a semiconductor device for signal processing can operate stably even when another semiconductor device operates.

### SUMMARY OF THE INVENTION

In an aspect of this disclosure, there is provided a semiconductor module that includes a first circuit board, a second circuit board, a first semiconductor device mounted on a first surface of the first circuit board, a second semiconductor device mounted on the second circuit board, and a radio wave absorber disposed between the first circuit board and the second circuit board.

### BRIEF DESCRIPTION OF THE DRAWINGS

FIG. 1 is a drawing illustrating a configuration of a semiconductor module according to a first embodiment;

FIG. 2 is an exploded perspective view of the semiconductor module according to the first embodiment;

FIG. 3 is a drawing illustrating a configuration of another semiconductor module according to the first embodiment;

FIGS. 4A and 4B are drawings illustrating a flexible board;

FIGS. 5A and 5B are drawings illustrating another flexible board;

FIG. 6 is a drawing illustrating an optical module according to a second embodiment;

FIG. 7 is a circuit diagram of an optical reception module according to the second embodiment;

FIG. 8 is a plan view of a first surface of a first circuit board according to the second embodiment;

FIG. 9 is a plan view of a second surface of the first circuit board according to the second embodiment;

FIGS. 10A and 10B are cross-sectional views of the optical module according to the second embodiment; and

FIG. 11 is a cross-sectional view of another optical module according to the second embodiment.

### DESCRIPTION OF EMBODIMENTS

Embodiments of the present invention are described below with reference to the accompanying drawings. Throughout the drawings, the same reference number is assigned to the same component, and repeated descriptions of the same component are omitted.

### First Embodiment

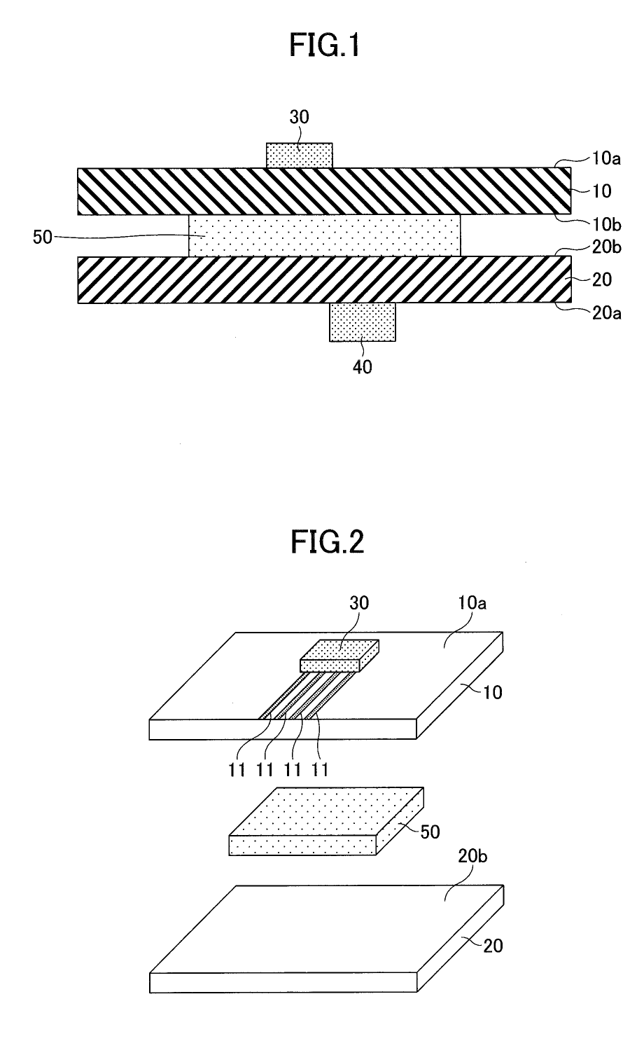

A semiconductor module according to a first embodiment is described with reference to FIGS. 1 and 2. FIG. 1 is a drawing illustrating a configuration of the semiconductor module according to the first embodiment, and FIG. 2 is an exploded perspective view of the semiconductor module.

The semiconductor module includes a first circuit board 10 and a second circuit board 20. A semiconductor device 30 is mounted on a surface 10a of the first circuit board 10. The semiconductor device 30 is, for example, a light emitter, a light receiver, an amplifier, or a signal processing semiconductor device. As illustrated in FIG. 2, wires 11 connected to the semiconductor device 30 are formed on the surface 10a. A semiconductor device 40 is mounted on a surface 20a of the second circuit board 20. The semiconductor device 40 is, for example, a semiconductor device that operates at a high frequency of 20 GHz. Wires (not shown) connected to the semiconductor device 40 are formed on the surface 20a.

The semiconductor module of the first embodiment includes a radio wave absorber 50 between the first circuit board 10 and the second circuit board 20. The wave absorber 50 disposed between the first circuit board 10 and the second circuit board 20 absorbs an electromagnetic wave generated when the semiconductor device 40 on the second circuit board 20 is operated. Thus, the wave absorber 50 reduces noise resulting from the electromagnetic wave and reduces the influence of the electromagnetic wave on the semiconductor device 30.

The wave absorber 50 absorbs an electromagnetic wave with a frequency greater than or equal to 10 MHz and less than or equal to 50 GHz, and is made of, for example, a material including carbonyl iron and silicone. The wave absorber 50 may also be referred to as a wave absorbing sheet and may be implemented by, for example, BSR-1 of Emerson & Cuming Microwave Products.

The drive frequency of the semiconductor device 40 is, for example, greater than or equal to 10 MHz and less than or equal to 50 GHz, and is more preferably greater than or equal to 1 GHz and less than or equal to 50 GHz. The electromagnetic wave absorbing effect of the wave absorber 50 increases as the thickness of the wave absorber 50 increases, and sufficient electromagnetic wave absorbing effect cannot be achieved if the thickness of the wave absorber 50 is small. However, excessively increasing the thickness of the wave absorber 50 results in an increase in the size of the semiconductor module and is therefore not preferable. The thickness of the wave absorber 50 is preferably greater than or equal to 0.25 mm and less than or equal to 1 mm.

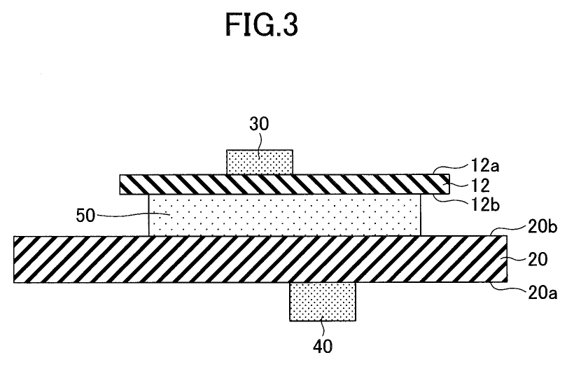

Also, as illustrated in FIG. 3, a flexible board 12 such as a flexible printed circuit (FPC) board may be used as a first circuit board. In this case, the semiconductor device 30 is mounted on a surface 12a of the flexible board 12, and the wave absorber 50 is provided between the flexible board 12 and the second circuit board 20.

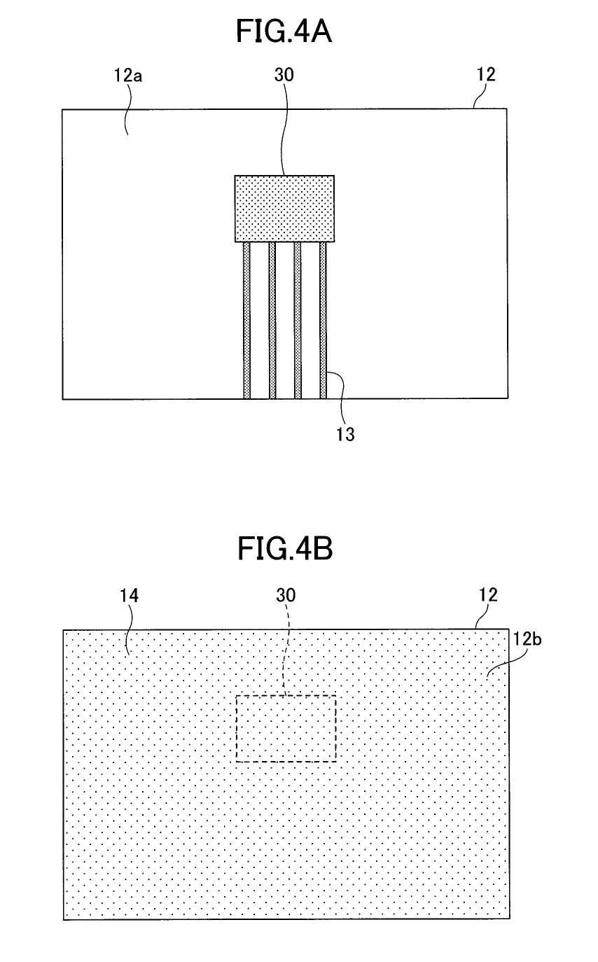

FIG. 4A illustrates the surface 12a of the flexible board 12, and FIG. 4B illustrates a surface 12b of the flexible board 12. The flexible board 12 includes two or more wiring layers. In FIGS. 4A and 4B, wires 13 connected to the semiconductor device 30 are formed on the surface 12a, and a ground electrode 14 is formed on the entire surface 12b.

One or more wires 13 for a ground potential are connected through, for example, a via to the ground electrode 14 formed on the surface 12b. Also, surfaces of the wires 13 and the ground electrode 14 may be covered with an insulating resin such as a polyimide resin

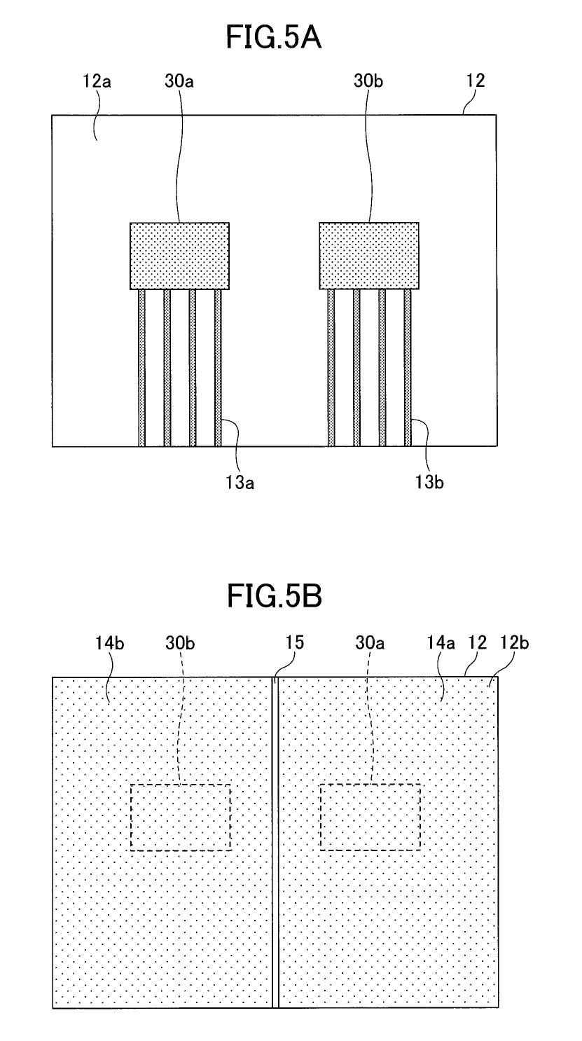

FIG. 5A illustrates the surface 12a of the flexible board 12, and FIG. 5B illustrates the surface 12b of the flexible board 12. As illustrated in FIG. 5A, two semiconductor devices 30a and 30b may be mounted on the surface 12a. In this case, wires 13a connected to the semiconductor device 30a and wires 13b connected to the semiconductor device 30b are formed on the surface 12a.

Two ground electrodes 14a and 14b corresponding to the semiconductor devices 30a and 30b may be formed on the surface 12b. In FIG. 5B, the ground electrode 14a for the semiconductor device 30a is formed in an area of the surface 12b corresponding to the semiconductor device 30a, and the ground electrode 14b for the semiconductor device 30b is formed in an area of the surface 12b corresponding to the semiconductor device 30b. If a single ground electrode is formed on the surface 12b, adjacent semiconductor devices may be influenced by each other via the ground electrode. Therefore, the ground electrodes 14a and 14b are separated from each other by a groove 15 in FIG. 5B. One or more wires 13a for a ground potential are connected through, for example, a via to the ground electrode 14a, and one or more wires 13b for a ground potential are connected through, for example, a via to the ground electrode 14b.

For example, the semiconductor device 30a is a trans-impedance amplifier (TIA) connected to a light emitter or a light receiver, and the semiconductor device 30b is a light emitter or a driver that is connected to and drives the light receiver.

### Second Embodiment

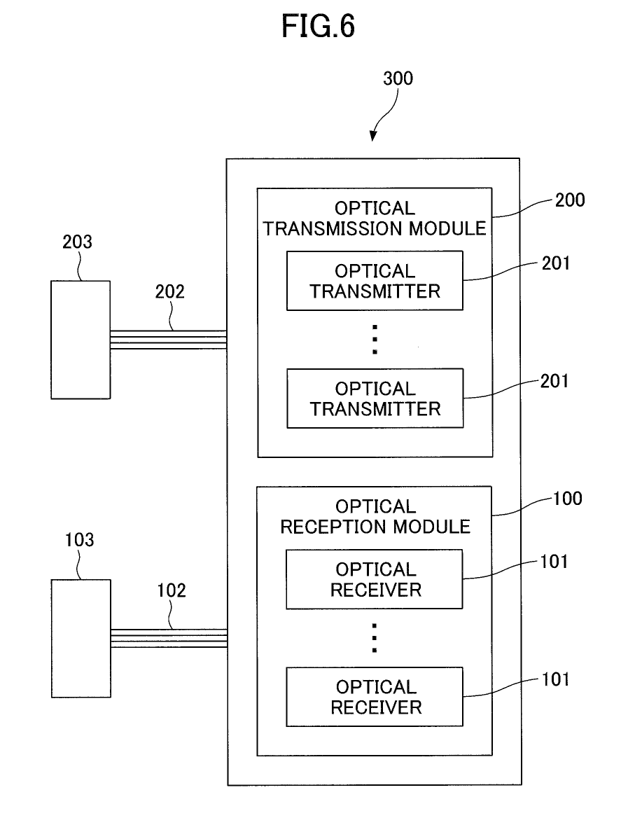

Next, an optical module according to a second embodiment is described. As illustrated in FIG. 6, the optical module of the second embodiment includes an optical engine 300 that includes an optical reception module 100 and an optical transmission module 200.

The optical reception module 100 includes multiple optical receivers 101. Each of the optical receivers 101 includes a light receiver and an amplifier that amplifies an electric signal output from the light receiver. An optical waveguide 102 is connected to the optical reception module 100, and cores in the optical waveguide 102 are optically connected to the corresponding optical receivers 101. A connector 103 is connected to the other end of the optical waveguide 102, and for example, an optical fiber (not shown) is connected to the connector 103. An optical signal transmitted through the optical fiber enters a core of the optical waveguide 102 via the connector 103, propagates through the core, and enters the corresponding optical receiver 101.

The optical transmission module 200 includes multiple optical transmitters 201. Each of the optical transmitters 201 includes a light emitter such as a vertical cavity surface emitting laser (VCSEL) and a driver that drives the light emitter to generate an optical signal from an electric signal. An optical waveguide 202 is connected to the optical transmission module 200, and cores in the optical waveguide 202 are optically connected to the corresponding optical transmitters 201. A connector 203 is connected to the optical waveguide 202, and for example, an optical fiber is connected to the connector 203. An optical signal output from the optical transmitter 201 enters a core of the optical waveguide 202, propagates through the core, and enters the optical fiber via the connector 203.

Each of the optical waveguide 102 and the optical waveguide 202 is formed of, for example, a resin and includes cores covered by clads. Each of the connector 103 and the connector 203 is, for example, an MT connector or a PMT connector.

### (Optical Reception Module)

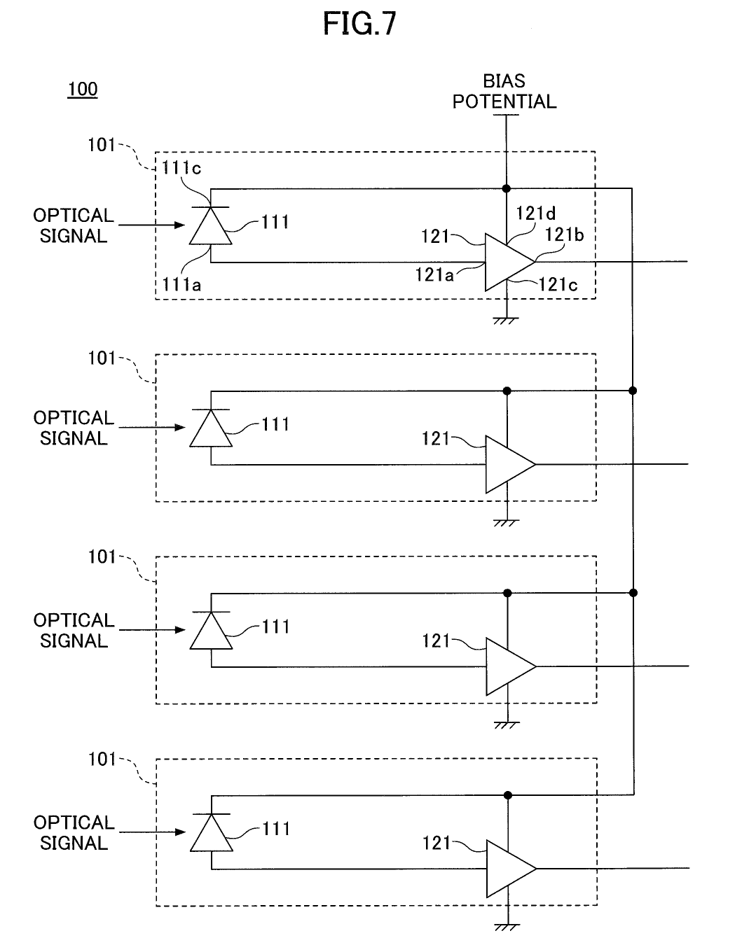

The optical reception module 100 is described with reference to FIG. 7.

As illustrated in FIG. 7, the optical reception module 100 includes four optical receivers 101. However, the number of the optical receivers 101 included in the optical reception module 100 is not limited to four.

Each optical receiver 101 includes a light receiver 111 and an amplifier 121. The light receiver 111 is, for example, a photodiode (PD) and includes an anode terminal 111a and a cathode terminal 111c. The amplifier 121 is, for example, a TIA and includes an input terminal 121a, an output terminal 121b, a ground terminal 121c, and a bias terminal 121d.

The anode terminal 111a is connected to the signal input terminal 121a, and the cathode terminal 111c is connected to the bias terminal 121d. When a bias potential is applied to the bias terminal 121d, the bias potential is also applied to the cathode terminal 111c. The ground terminal 121c of the amplifier circuit 121 is grounded.

When an optical signal is input to the light receiver 111, a current signal corresponding to the strength of the optical signal is input to the input terminal 121a, and the amplifier 121 amplifies the current signal from the light receiver 111 and outputs the amplified signal from the output terminal 121b.

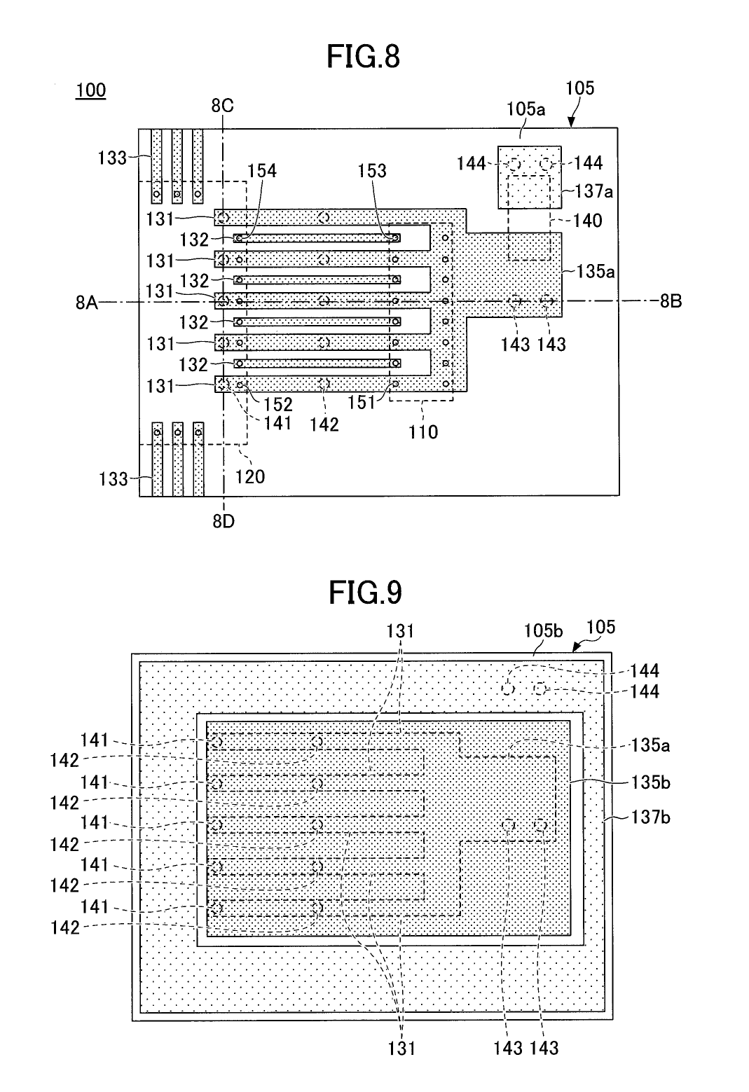

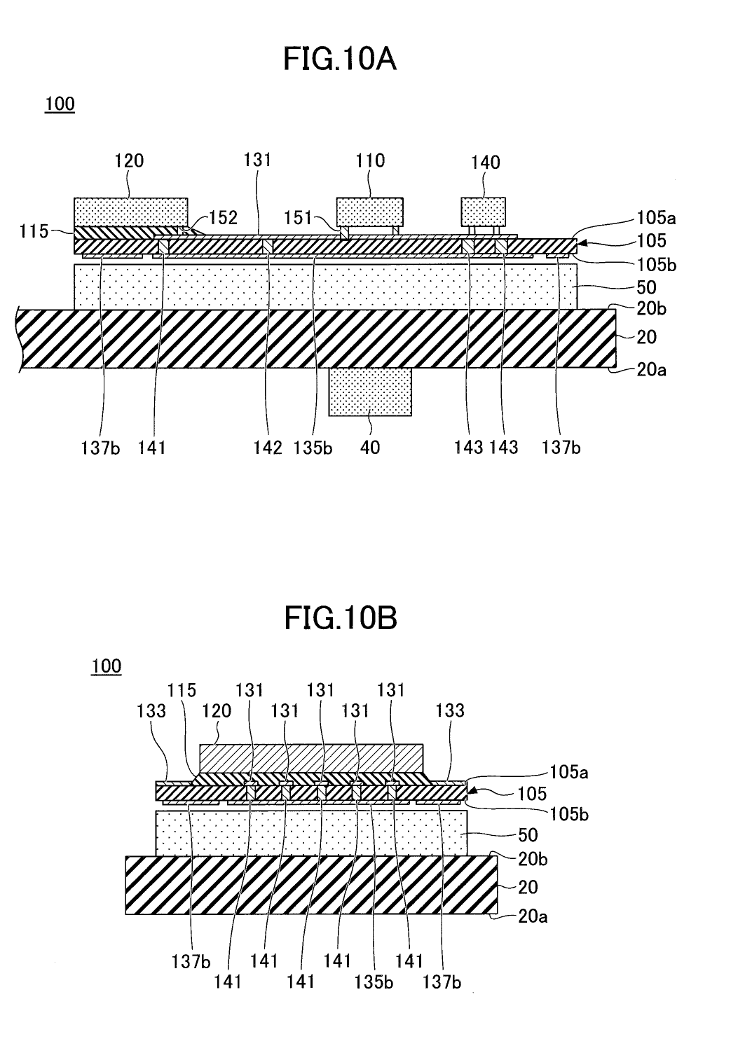

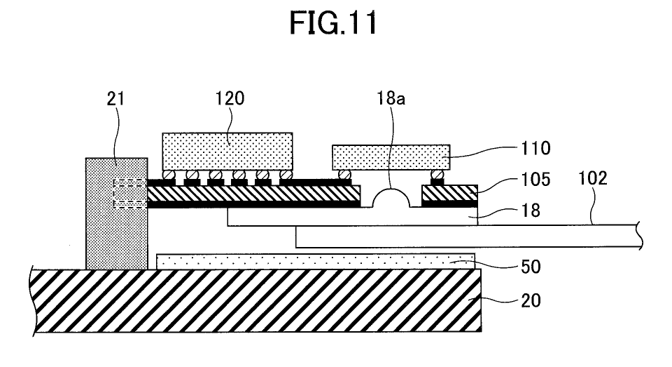

FIG. 8 is a plan view of the upper surface of a first circuit board 105, and FIG. 9 is a plan view of the lower surface of the first circuit board 105. FIG. 10A is a cross-sectional view of the optical reception module 100 taken along line 8A-8B of FIG. 8, and FIG. 10B is a cross-sectional view of the optical reception module 100 taken along line 8C-8D of FIG. 8.

In the second embodiment, as illustrated in FIGS. 10A and 10B, the second circuit board 20 is provided to face a surface 105b of a first circuit board 105, and the wave absorber 50 is provided between the first circuit board 105 and the second circuit board 20. In the second embodiment, the first circuit board 105 may be an FPC board. The semiconductor device 40 is mounted on the surface 20a of the second circuit board 20.

In the optical reception module 100, as illustrated in FIG. 8, a light-receiving module 110, an amplifier module 120, and a capacitance 140 are mounted on a surface 105a of the first circuit board 105. In FIG. 8, the light-receiving module 110, the amplifier module 120, and the capacitance 140 are indicated by dotted lines.

The light-receiving module 110 includes multiple light receivers 111 (see FIG. 7), and the amplifier module 120 includes multiple amplifiers 121 (see FIG. 7) corresponding to the light receivers. For example, the light-receiving module 110, the amplifier module 120, and the capacitance 140 are mounted on the surface 105a by flip-chip mounting. As illustrated in FIGS. 10A and 10B, the amplifier module 120 is fixed to the first circuit board 105 by an under fill 115 that fills a space between the amplifier module 120 and the first circuit board 105.

As illustrated in FIG. 8, multiple cathode wirings 131, multiple anode wirings 132, control signal lines 133, a bias electrode 135a, and a ground electrode 137a are formed on the surface 105a.

The cathode wirings 131 are integrated with the bias electrode 135a and extend from the bias electrode 135a like a comb. Each anode wiring 132 is disposed between two cathode wirings 131. That is, the cathode wirings 131 and the anode wirings 132 are arranged alternately.

Each cathode wiring 131 is connected to a cathode terminal of a light receiver 111 at a joint 151. Also, each cathode wiring 131 is connected to a bias terminal of an amplifier 121 at a joint 152. Thus, each cathode wiring 131 electrically connects the cathode terminal of the light receiver 111 and the bias terminal of the amplifier 121 via the joint 151 and the joint 152.

Each anode wiring 132 is connected to an anode terminal of a light receiver 111 at a joint 153. Also, each anode wiring 132 is connected to an input terminal of an amplifier 121 at a joint 154. Thus, each anode wiring 132 electrically connects the anode terminal of the light receiver 111 and the input terminal of the amplifier 121 via the joint 153 and the joint 154.

The light receivers 111 are connected to the amplifiers 121 via the cathode wirings 131 and the anode wirings 132 to form the optical receivers 101 illustrated in FIG. 7.

The control signal lines 133 are connected to control terminals of the amplifier module 120 to input control signals to the amplifier module 120.

A bias potential is applied to the bias electrode 135a that is integrated with the cathode wirings 131. The capacitance 140 is provided between the bias electrode 135a and the ground electrode 137a.

As illustrated in FIG. 9, a bias electrode 135b and a ground electrode 137b are formed on the surface 105b of the first circuit board 105. In FIG. 9, the cathode wirings 131 and the bias electrode 135a are indicated by dotted lines.

The bias electrode 135b is formed in an area of the surface 105b corresponding to an area on the surface 105a that includes the cathode wirings 131 and the bias electrode 135a. The ground electrode 137b is formed on the periphery of the surface 105b to surround the bias electrode 135b. The bias electrode 135b and the ground electrode 137b are separated from each other, and a conductor portion around the ground electrode 137b is removed.

As illustrated in FIGS. 8 and 9, each cathode wiring 131 is connected to the bias electrode 135b through a bias via 141 and a bias via 142. Also, the bias electrode 135a and the bias electrode 135b are connected to each other through electrode vias 143.

A bias potential is applied from a voltage source to one of the bias electrode 135a and the bias electrode 135b. As a result, the bias electrode 135a and the bias electrode 135b connected to each other through the electrode vias 143 assume the same bias potential. Accordingly, the bias potential is applied to the cathode wirings 131 from the bias electrode 135a and the bias electrode 135b that is connected to the cathode wirings 131 through the bias vias 141 and the bias vias 142.

The ground electrode 137a is connected through ground vias 144 to the ground electrode 137b, and the ground electrode 137a and the ground electrode 137b assume the same ground potential.

Each anode wiring 132 is disposed between two cathode wirings 131 to which the same bias potential is applied. This reduces the crosstalk between adjacent anode wirings 132.

As illustrated in FIG. 8, the bias via 141 is formed in a position that is close to the joint 152 and close to a connection point between the bias terminal of the amplifier 121 and the cathode wiring 131. The potential variation between the light receiver 111 and the amplifier 121 is reduced and a constant bias potential is maintained by connecting the cathode wiring 131 to the bias electrode 135b through the bias via 141 near a connection point between the cathode wiring 131 and the bias terminal of the amplifier 121.

Maintaining a constant bias potential of the cathode wiring 131 between the light receiver 111 and the amplifier 121 reduces the variation of an electric field formed between the cathode wiring 131 and the anode wiring 132 and improves the effect of reducing crosstalk. Accordingly, the high-speed signal transmission characteristic of the optical reception module 100 is improved.

The reception sensitivity of the optical module of the present embodiment and the reception sensitivity of an optical module of a comparative example were measured. The optical module of the present embodiment includes the wave absorber 50 between the first circuit board 105 and the second circuit board 20, and the optical module of the comparative example does not include the wave absorber 50 between the first circuit board 105 and the second circuit board 20.

As indicated in Table 1 below, the reception sensitivity of the optical module of the present embodiment is −7.77 dBm. The reception sensitivity of the optical module of the comparative example is −7.51 dBm. Thus, with the optical module of the present embodiment, the reception sensitivity is improved by 0.26 dB.

TABLE 1

WAVE
ABSORBING
SHEET

| | NO | YES |
|---|---|---|
| RECEPTION | −7.51 | −7.77 |
| SENSITIVITY | | |
| [dBm] | | |
| DIFFERENCE [dB] | | 0.26 |

The optical module of the second embodiment may also have a configuration as illustrated in FIG. 11. In FIG. 11, in addition to the light-receiving module 110 and the amplifier module 120, a light-emitting module and a driver module for driving the light-emitting module are mounted on the first circuit board 105. The first circuit board 105 is disposed such that the light-receiving module 110, the amplifier module 120, the light-emitting module, and the driver module are located above the wave absorber 50 attached to the second circuit board 20. The wave absorber 50 can absorb and weaken an electromagnetic wave that may cause noise in semiconductor devices and wires provided on a surface of the second circuit board 20 that is opposite the surface on which the wave absorber 50 is attached.

In the optical module illustrated in FIG. 11, a lens sheet 18 including multiple lenses 18a is provided between the first circuit board 105 and the optical waveguide 102, and a connection terminal of the first circuit board 105 is connected to a connector 21 provided on the second circuit board 20.

An aspect of this disclosure provides a semiconductor module where a semiconductor device for signal processing can stably operate.

Semiconductor modules according to embodiments of the present invention are described above. However, the present invention is not limited to the embodiments, and variations and modifications may be made without departing from the scope of the present invention.

What is claimed is:

1. A semiconductor module, comprising:
a first circuit board;
a second circuit board;
a first semiconductor device mounted on a first surface of the first circuit board;
a second semiconductor device mounted on the second circuit board; and
a radio wave absorber disposed between the first circuit board and the second circuit board.

2. The semiconductor module as claimed in claim 1, wherein the first circuit board is a flexible board.

3. The semiconductor module as claimed in claim 1, further comprising:
a ground electrode formed on a second surface of the first circuit board.

4. The semiconductor module as claimed in claim 1, wherein
the first semiconductor device includes a photodiode; and
the semiconductor module further comprises:
an anode wiring and a cathode wiring that are for the photodiode and formed on the first surface of the first circuit board,
a bias electrode that is formed on a second surface of the first circuit board and covers an area corresponding to the anode wiring and the cathode wiring, and
a ground electrode that is formed on the second surface of the first circuit board and surrounds the bias electrode.
